(19) United States
(12) Patent Application Publication
(10) Pub. No.: US 2008/0247570 A1
(43) Pub. Date: Oct. 9, 2008

(54) Sound output device with earphone mode and speaker mode

(75) Inventors: Yin-Yu Lin, Hsin Tien (TW); Chih-Lung Chang, Hsin-Tien (TW); Yen-Bo Lai, Hsin Tien (TW)

Correspondence Address: RABIN & Berdo, PC, 1101 14TH STREET, NW, SUITE 500, WASHINGTON, DC, 20005, US

(73) Assignee: GIGA-BYTE TECHNOLOGY CO., LTD., Taipei County (TW)

(21) Appl. No.: 11/730,676

(22) Filed: Apr. 3, 2007

(51) Int. Cl. H03G 3/00

(52) U.S. Cl. 381/104

(57) ABSTRACT

A sound output device with an earphone mode and a speaker mode is provided. The sound output device changes a circuit resistance value of loudspeaker modules by adjusting a connecting state of the loudspeaker modules in the sound output device. Thus the sound output device is set to an output volume value of the earphone mode or of the speaker mode, so as to meet the requirements of the user, and to improve the convenience in use of the sound output device.

### BACKGROUND OF THE INVENTION

1. Field of the Invention

The present invention relates to a sound output device, and more particularly, to a sound output device with an earphone mode and a speaker mode.

2. Related Art

With the coming of the multimedia era, a user can enjoy the entertaining effect brought about by the multimedia anywhere and anytime. For example, the user can play and enjoy audio and video with an audio/video player device or the like, and the above described manners for enjoying the entertaining effect are achieved through a display, a speaker or an earphone according to the user's demands. In an environment that allows high volume, a user outputs a sound effect by connecting the speaker to a speaker output of the video player device, and controls the output volume with a volume adjusting knob on the speaker. While, in an environment that allows lower volume only or when the user intends to appreciate the music alone, the user needs to connect the earphone to an earphone jack of the video player device for outputting the sound effect. However, most of the earphones don't have volume adjusting knobs. Therefore, when the user wants to adjust the output volume of an earphone, a volume output value on the video player device must be set to adjust the volume output by the earphone, which is inconvenient in use.

Furthermore, the speaker and the earphone are generally two independent products. That is to say, when the two products are needed, the user has to buy both them and connect/disconnect the speaker or the earphone to the video player device according to the requirement in use. Moreover, if the user forgets to carry the speaker or the earphone, the user can only appreciate the audio and video played by the video player device with one of speaker or the earphone only. Therefore, in addition to the inconvenience in use, the convenience in carrying is also to be improved.

### SUMMARY OF THE INVENTION

In view of the above described problems, the present invention is to provide a sound output device with an earphone mode and a speaker mode, which changes a circuit resistance value of loudspeaker modules by adjusting a connecting state of the loudspeaker modules in the sound output device. Thus, the sound output device is set to the earphone mode or the speaker mode, so as to meet the requirements in use.

The sound output device with an earphone mode and a speaker mode according to the disclosure of the present invention includes a first loudspeaker module and a second loudspeaker module. The first loudspeaker module has a sound source signal input interface for receiving a sound source signal, and a first connecting point for adjusting an output volume value. The second loudspeaker module is electrically coupled to the sound source signal input interface and has a second connecting point for adjusting the output volume.

When the first connecting point is not electrically coupled to the second connecting point, the circuit resistance values of the first loudspeaker module and the second loudspeaker module are invariable, and the first loudspeaker module and the second loudspeaker module output a first volume value respectively. Therefore, the sound output device is set to a speaker mode. While the first connecting point is electrically coupled to the second connecting point, the circuit resistance values of the first loudspeaker module and the second loudspeaker module reduce, and the first loudspeaker module and the second loudspeaker module output a second volume value which is lower than the first volume value respectively. Therefore, the sound output device is set to an earphone mode.

The sound output device with an earphone mode and a speaker mode according to the disclosure of the present invention integrates the earphone and the speaker into a same sound output device. Therefore, the user will not have the trouble of forgetting to carry the speaker or the earphone, and it is more convenient in carrying than the prior art.

In the sound output device with an earphone mode and a speaker mode according to the disclosure of the present invention, when the sound output device is set to the earphone mode, the user can still adjust the output volume value through a volume adjusting unit.

By using the sound output device with an earphone mode and a speaker mode, in an environment that allows a high volume, the sound output device is set to the speaker mode through electrically coupling the volume adjusting connecting points of each of the loudspeaker modules to one another. While in an environment that allows a low volume or when the user intends to appreciate the music alone, the sound output device is set to the earphone mode through separating the electrically coupled volume adjusting connecting points of each of the loudspeaker modules. Therefore, the user achieves the objection of setting the output mode of the sound output device rapidly through a simple operating manner, and avoids the trouble of forgetting to carry the speaker or the earphone. Therefore, it is more convenient in carrying than the prior art.

As for features and practices of the present invention, the preferred embodiments are illustrated below in detail with reference to the drawings.

Further scope, of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and thus is not limitative of the present invention, and wherein:

FIG. 1 is a schematic circuit diagram of a first embodiment of the present invention;

FIG. 2 is a schematic circuit diagram of a second embodiment of the present invention;

FIG. 3 is a schematic circuit diagram of a third embodiment of the present invention; and

FIG. 4 is a schematic circuit diagram of a fourth embodiment of the present invention.

### DETAILED DESCRIPTION OF THE INVENTION

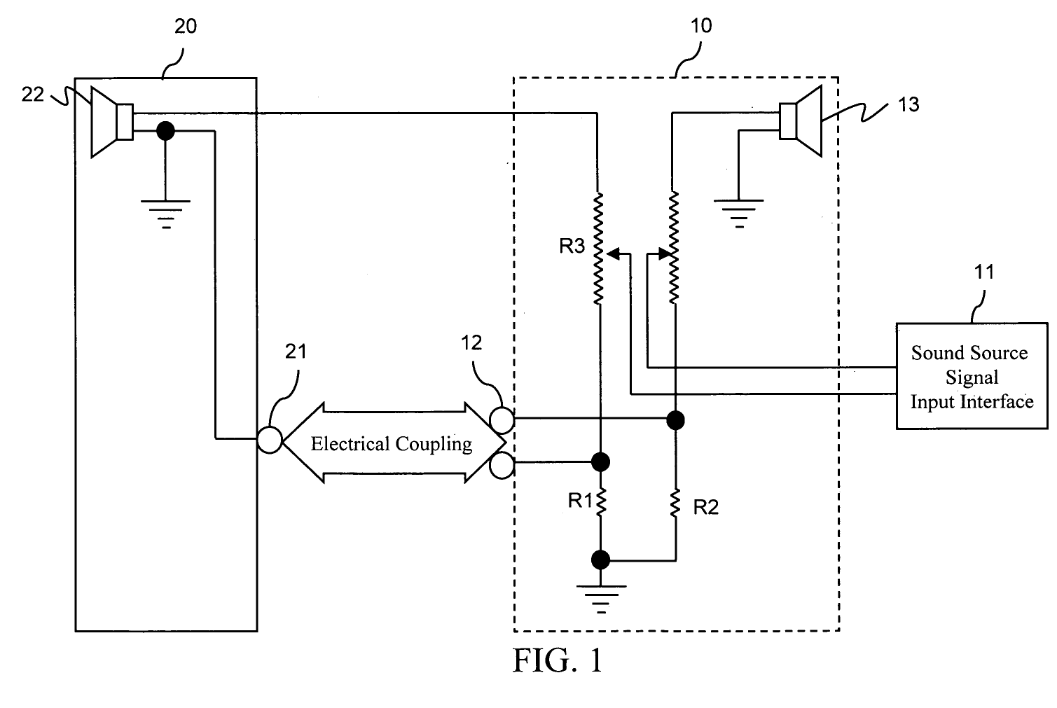

FIG. 1 is a schematic circuit diagram of a first embodiment of the present invention. As shown in FIG. 1, a sound output device with an earphone mode and a speaker mode of the first embodiment of the present invention includes a first loudspeaker module 10 and a second loudspeaker module 20. Each module will be illustrated below.

The first loudspeaker module 10 includes a sound source signal input interface 11, a first connecting point 12, a first speaker 13, a first resistor. R1, a second resistor R2, and a volume adjusting unit R3. Wherein, the sound source signal input interface 11 is electrically coupled to the volume adjusting unit R3 for receiving a sound source signal from an external equipment (for example, a video player device), and the sound source signal input interface 11, for example, can be an audio jack. The first connecting point 12 is electrically coupled to the first resistor R1 and the second resistor R2, for adjusting an output volume value. The first speaker 13 is electrically coupled to the volume adjusting unit R3, for producing a sound effect corresponding to the sound source signal. The first resistor R1 and the second resistor R2 are electrically coupled to the volume adjusting unit R3, for changing the circuit resistance values of the first loudspeaker module 10 and the second loudspeaker module 20 when the first connecting point 12 is electrically coupled to a second connecting point 21. The volume adjusting unit R3 is electrically coupled with the sound source signal input interface 11, the first resistor R1, the second resistor R2, the first speaker 13, and a second speaker 22 respectively. Therefore, a user can adjust the circuit resistance values of the first loudspeaker module 10 and the second loudspeaker module 20. Wherein, the volume adjusting unit R3, for example, can be a variable resistor component.

The second loudspeaker module 20 has the second connecting point 21 and the second speaker 22. The second loudspeaker module 20 is electrically coupled to the sound source signal input interface 11 through the volume adjusting unit R3. Wherein, the second connecting point 21 is electrically coupled to the second speaker 22 for adjusting the output volume value. The second speaker 22 is electrically coupled to the volume adjusting unit R3 for producing the sound effect corresponding to the sound source signal.

Hereafter, the operating principle of the circuit will be illustrated.

Firstly, when the first connecting point 12 is not electrically coupled to the second connecting point 21, the sound output device is set to the speaker mode, and the circuit resistance values of the first loudspeaker module 10 and the second loudspeaker module 20 are decided by the volume adjusting unit R3, the first resistor R1, and the second resistor R2. That is to say, when the first connecting point 12 is not electrically coupled to the second connecting point 21, the volume adjusting unit R3 is connected with the first resistor R1 and the second resistor R2 in series, so the circuit resistance value is higher. Therefore, the output power of the first loudspeaker module 10 and the second loudspeaker module 20 is higher, and relatively, the volume output value (i.e., the first volume value) of the first speaker 13 and the second speaker 22 is also higher.

When the first connecting point 12 is electrically coupled to the second connecting point 21, the sound output device is set to the earphone mode. The volume adjusting unit R3 is in parallel connection with the first resistor R1 and the second resistor R2, so the circuit resistance value is lower. Therefore, the output power of the first loudspeaker module 10 and the second loudspeaker module 20 is lower, and relatively, the volume output value (i.e., the second volume value) of the first speaker 13 and the second speaker 22 is also lower. Wherein, the electrically coupling between the first connecting point 12 and the second connecting point 21 can be realized, for example, through a metal wire or a fixing frame with metal wires buried in. While the fixing frame can be a slightly arc-shaped spatial structure for fixing the first loudspeaker module 10 and the second loudspeaker module 20 on two sides of the fixing frame respectively, such that the first loudspeaker module 10 and the second loudspeaker module 20 become a headphone (but not limited to the forms).

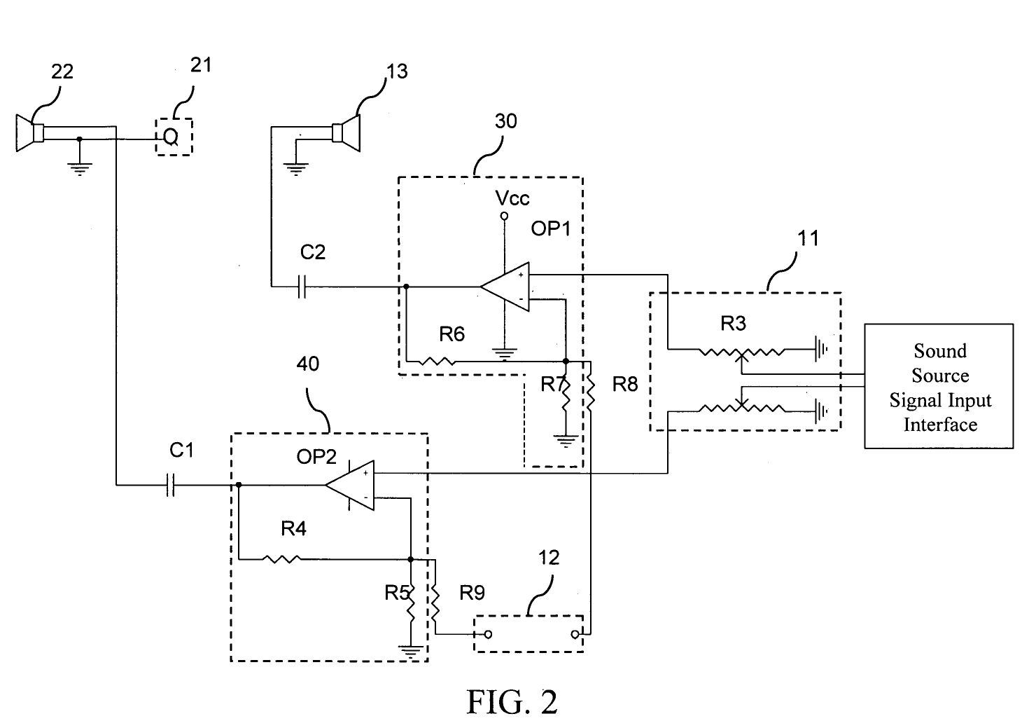

FIG. 2 is a schematic circuit diagram of a second embodiment of the present invention. As shown in FIG. 2, the sound output device with an earphone mode and a speaker mode of the second embodiment of the present invention includes the sound source signal input interface 11, the volume adjusting unit R3, a first signal amplifying unit 30, a second signal amplifying unit 40, the first connecting point 12, the second connecting point 21, the first speaker 13, and the second speaker 22. Each of the modules and units will be illustrated below.

The sound source signal input interface 11 is electrically coupled to the volume adjusting unit R3, for receiving a sound source signal from an external equipment (for example, the video player device), and the sound source signal input interface 11 can be, for example, the audio jack.

The volume adjusting unit R3 is electrically coupled to the sound source signal input interface 11, the first signal amplifying unit 30, and the second signal amplifying unit 40. Thus, the user can adjust the circuit resistance values of the first speaker 13 and the second speaker 22. Wherein, the volume adjusting unit R3 can be, for example, a variable resistor component.

The first signal amplifying unit 30 is electrically coupled to the sound source adjusting unit R3, for amplifying the sound source signal, and outputting the amplified sound source signal to the first speaker 13. Wherein, the first signal amplifying unit 30 includes a first operational amplifier OP1, a sixth resistor R6, and a seventh resistor R7. A first input terminal (i.e., a non-inverted input terminal) of the first operational amplifier OP1 is electrically coupled to a first terminal of the volume adjusting unit R3. A second input terminal (i.e., an inverted input terminal) of the first operational amplifier OP1 is electrically coupled to a second terminal of the sixth resistor R6, a first terminal of the seventh, resistor R7, and a first terminal of the eighth resistor R8. An output terminal of the operational amplifier OP1 is electrically coupled to a first terminal of a second capacitor C2 and a first terminal of the sixth resistor R6. A second terminal of the seventh resistor R7 is electrically coupled to a ground terminal, and a second terminal of the eighth resistor R8 is electrically coupled to a first terminal of the first connecting point 12.

The second signal amplifying unit 40 is electrically coupled to the sound source adjusting unit R3 for amplifying the sound source signal, and outputting the amplified sound source signal to the second speaker 22. Wherein, the second signal amplifying unit 40 includes a second operational amplifier OP2, a fourth resistor R4 and a fifth resistor R5. A first input terminal (i.e., the non-inverted input terminal) of the second operational amplifier OP2 is electrically coupled to a second terminal of the volume adjusting unit R3. A second input terminal (i.e., an inverted input terminal) of the second operational amplifier OP2 is electrically coupled to a second terminal of the fourth resistor R4, a first terminal of the fifth resistor R5, and a first terminal of a ninth resistor R9. An output terminal of the operational amplifier OP2 is electrically coupled to a first terminal of a first capacitor C1 and a first terminal of the fourth resistor R4. A second terminal of the fifth resistor R5 is electrically coupled to a ground terminal, and a second terminal of the ninth resistor R9 is electrically coupled to a second terminal of the first connecting point 12.

The first speaker 13 is electrically coupled to the first signal amplifying unit 30 for producing the sound effect corresponding to the amplified sound source signal. A first input terminal of the first speaker 13 is electrically coupled to a second terminal of the second capacitor C2, and a second input terminal of the first speaker 13 is electrically coupled to the ground terminal.

The second speaker 22 is electrically coupled to the second signal amplifying unit 40 for producing the sound effect corresponding to the amplified sound source signal. A first input terminal of the second speaker 22 is electrically coupled to a second terminal of the first capacitor C1, and the second input terminal of the first speaker 13 is electrically coupled to the ground terminal and the second connecting point 21.

Hereafter, the operating principle of the circuit will be illustrated.

Firstly, when the first connecting point 12 is not electrically coupled to the second connecting point 21, the sound output device is set to the speaker mode. The circuit resistance value of the first signal amplifying unit 30 is decided by connecting the sixth resistor R6 and the seventh resistor R7 in series, and the circuit resistance value of the second signal amplifying unit 40 is decided by connecting the fourth resistor R4 and the fifth resistor R5 in series, so the circuit resistance values are higher. Therefore, the output power of the first speaker 13 and the second speaker 22 is higher, and relatively, the volume output value (i.e., the first volume value) of the first speaker 13 and the second speaker 22 is also higher.

When the first connecting point 12 is electrically coupled to the second connecting point 21, the sound output device is set to the earphone mode. The circuit resistance value of the first signal amplifying unit 30 is decided by connecting the seventh resistor R7 and the eighth resistor R8 in parallel and then connecting them with the sixth resistor R6 in series. While the circuit resistance value of the second signal amplifying unit 40 is decided by connecting the fourth resistor R4 and the fifth resistor R5 in parallel and then connecting them to the ninth resistor R9 in series, so the circuit resistance values are lower. Therefore, the output power of the first speaker 13 and the second speaker 22 is lower, and relatively, the volume output value (i.e., the second volume value) of the first speaker 13 and the second speaker 22 is also lower. The first capacitor C1 and the second capacitor C2 are used to isolate a direct current (DC) bias, and to prevent the DC current from entering the first speaker 13 and the second speaker 22.

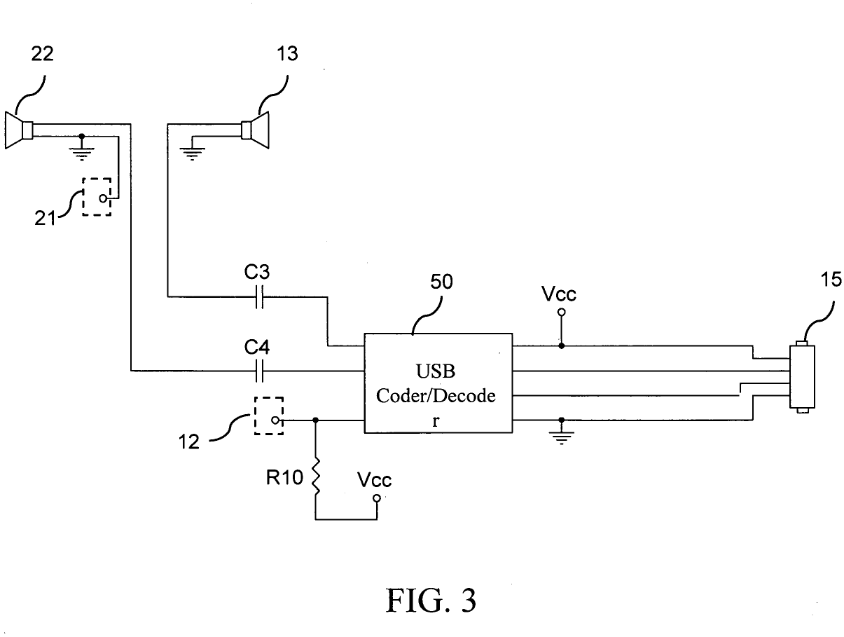

FIG. 3 is a schematic circuit diagram of a third embodiment of the present invention. As shown in FIG. 3, the sound output device with an earphone mode and a speaker mode of the third embodiment of the present invention includes a volume output control module having a universal serial bus (USB) transmission interface 15 and a USB coder/decoder 50, the first connecting point 12, the second connecting point 21, the first speaker 13 and the second speaker 22. Each of the modules will be illustrated below.

The USB transmission interface 15 is electrically coupled to the USB coder/decoder 50 for receiving the sound source from an external equipment (for example, the video play equipment) and a power Vcc.

The USB coder/decoder 50 is electrically coupled to the USB transmission interface 15 for amplifying the sound source signal and outputting it to the first speaker 13 and the second speaker 22.

The first connecting point 12 is electrically coupled to the USB coder/decoder 50. Wherein, a first terminal of a tenth resistor R10 is electrically coupled to the USB coder/decoder 50 and the first connecting point 12, and the second connecting point 21 is electrically coupled to the second speaker 22.

The first terminal of the first speaker 13 is electrically coupled to the USB coder/decoder 50. Wherein, a third capacitor C3 is serially connected between the first speaker 13 and the USB coder/decoder 50, and the second terminal of the first speaker 13 is electrically coupled to the ground terminal.

The first terminal of the second speaker 22 is electrically coupled to the USB coder/decoder 50. Wherein, a fourth capacitor C4 is serially connected between the second speaker 22 and the USB coder/decoder 50, and the second terminal of the first speaker 13 is electrically coupled to the ground terminal and the second connecting point 21.

Hereafter, the operating principle of the circuit will be illustrated.

Firstly, when the first connecting point 12 is not electrically coupled to the second connecting point 21, the sound output device is set to the speaker mode. The USB coder/decoder 50 decides an amplitude value for amplifying the sound source signal according to a divided voltage value of the tenth resistor R10. Therefore, according to the divided voltage value (for example, a high level voltage signal) of the tenth resistor RIO, the USB coder/decoder 50 outputs the sound source signal with a first amplitude value to the first speaker 13 and the second speaker 22. Therefore, the first speaker 13 and the second speaker 22 output the first volume value. In each embodiment of the present invention, the first volume value is higher than the second volume value.

When the first connecting point 12 is electrically coupled to the second connecting point 21, the sound output device is set to the earphone mode. The USB coder/decoder 50 decides the amplitude value for amplifying the sound source signal according to a divided voltage value of the tenth resistor R10. Thus, according to the divided voltage value (for example, a low level voltage signal) of the tenth resistor R10, the USB coder/decoder 50 outputs the sound source signal with a second amplitude value to the first speaker 13 and the second speaker 22. Therefore, the first speaker 13 and the second speaker 22 output the second volume value. In each embodiment of the present invention, the second volume value is lower than the first volume value. The third capacitor C3 and the fourth capacitor C4 are used to isolate the DC bias, and to prevent the direct current from entering the first speaker 13 and the second speaker 22.

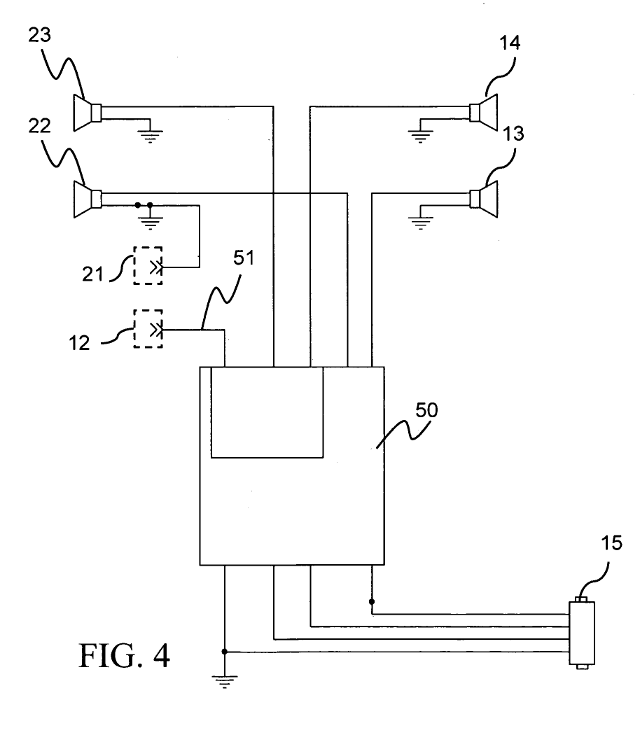

FIG. 4 is a schematic circuit diagram of the fourth embodiment of the present invention. As shown in FIG. 4, the sound output device with an earphone mode and a speaker mode of a fourth embodiment of the present invention includes a volume output control module having the USB transmission interface 15, the USB coder/decoder 50, the first connecting point 12, the second connecting point 21, the first speaker 13, the second speaker 22, a third speaker 14, and a fourth speaker 23. Each of the modules will be illustrated below.

The USB transmission interface 15 is electrically coupled to the USB coder/decoder 50 for receiving the sound source signal from the external equipment (for example, the video player device) and a power Vcc.

The USB coder/decoder 50 is electrically coupled to the USB transmission interface 15 for amplifying the sound source signal and outputting it to the first speaker 13, the second speaker 22, the third speaker 14, and the fourth speaker 23.

The first connecting point 12 is electrically coupled to an enable pin 51 of the USB coder/decoder 50. While the second connecting point 21 is electrically coupled to the second speaker 22.

The first terminal of the first speaker 13 is electrically coupled to the USB coder/decoder 50, and the second terminal of the first speaker 13 is electrically coupled to the ground terminal.

The first terminal of the second speaker 22 is electrically coupled to the USB coder/decoder 50, and the second terminal of the first speaker 13 is electrically coupled to the ground terminal and the second connecting point 21.

The first terminal of the third speaker 14 is electrically coupled to the USB coder/decoder 50, while the second terminal of the third speaker 14 is electrically coupled to the ground terminal.

The first terminal of the fourth speaker 23 is electrically coupled to the USB coder/decoder 50, and the second terminal of the fourth speaker 23 is electrically coupled to the ground terminal.

Hereafter, the operating principle of the circuit will be illustrated.

Firstly, when the first connecting point 12 is not electrically coupled to the second connecting point 21, the sound output device is set to the speaker mode, and the USB coder/decoder 50 decides whether to output the amplified sound source signal to the first speaker 13, the second speaker 22, the third speaker 14, or the fourth speaker 23 according to a level signal of the speaker enable pin 51. Thus, according to the relationship that the speaker enable pin 51 is electrically coupled to the ground terminal, the USB coder/decoder 50 enables to output the amplified sound source signal to the first speaker 13, the second speaker 22, the third speaker 14, and the fourth speaker 23. Therefore, the volume value output simultaneously by the four speakers is higher than the volume value output simultaneously by the two speakers.

When the first connecting point 12 is electrically coupled to the second connecting point 21, the sound output device is set to the earphone mode, and the USB coder/decoder 50 decides whether to output the amplified sound source signal to the first speaker 13, the second speaker 22, the third speaker 14 or the fourth speaker 23 according to the level signal of the speaker enable pin 51. Thus, according to the relationship that the speaker enable pin 51 is not electrically coupled to the ground terminal, the USB coder/decoder 50 disables to not output the amplified sound source signal to the third speaker 14 and the fourth speaker 23. Therefore, the volume value output simultaneously by the two speakers is lower than the volume value output simultaneously by the four speakers.

To sum up, by using the sound output device with an earphone mode and a speaker mode of the present invention, in an environment that allows a high volume, the sound output device is set to the speaker mode by electrically coupling the volume adjusting connecting points in each loudspeaker module to one another; in the environment that allows a low volume or when the user intends to appreciate the music alone, the sound output device is set to the earphone mode through separating the electrically coupled volume adjusting connecting points in each loudspeaker module. Thus, the user can set the output mode of the sound output device rapidly through an easy operating manner, and avoids the trouble of forgetting to carry the speaker or the earphone. Therefore, the convenience in carrying is also better than the prior art.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A sound output device with an earphone mode and a speaker mode, comprising:
a first loudspeaker module, having a sound source signal input interface for receiving a sound source signal, and a first connecting point for adjusting an output volume value; and
a second loudspeaker module, electrically coupled to the sound source signal input interface, and having a second connecting point for adjusting the output volume value;
wherein when the first connecting point is not electrically coupled to the second connecting point, circuit resistance values of the first loudspeaker module and the second loudspeaker module are invariable, and the first loudspeaker module and the second loudspeaker module output a first volume value respectively;
when the first connecting point is electrically coupled to the second connecting point, the circuit resistance values of the first loudspeaker module and the second loudspeaker module reduce, and the first loudspeaker module and the second loudspeaker module output a second volume value lower than the first volume value respectively.

2. The sound output device with an earphone mode and a speaker mode as claimed in claim 1, further comprising a volume adjusting unit, electrically coupled to the first loudspeaker module and the second loudspeaker module respectively, for providing operation of a user, so as to change the circuit resistance values of the first loudspeaker module and the second loudspeaker module.

3. The sound output device with an earphone mode and a speaker mode as claimed in claim 2, wherein the volume adjusting unit is a variable resistor.

4. The sound output device with an earphone mode and a speaker mode as claimed in claim 2, further comprising:
a first signal amplifying unit, electrically coupled to the sound source adjusting unit, for amplifying the sound source signal, and outputting the amplified sound source signal to the first loudspeaker module; and
a second signal amplifying unit, electrically coupled to the sound source adjusting unit, for amplifying the sound source signal, and outputting the amplified sound source signal to the second loudspeaker module.

5. The sound output device with an earphone mode and a speaker mode as claimed in claim 1, wherein the sound source signal input interface is a Universal Serial Bus (USB) transmission interface.

6. The sound output device with an earphone mode and a speaker mode as claimed in claim 5, further comprising a USB coder/decoder electrically coupled to the USB transmission interface, wherein the USB coder/decoder is used for amplifying the sound source signal, and for selectively driving the first loudspeaker module and the second loudspeaker module to output the first volume value or the second volume value.

7. The sound output device with an earphone mode and a speaker mode as claimed in claim 6, wherein when the USB coder/decoder is not electrically coupled to a ground terminal of the first loudspeaker module or the second loudspeaker module, the first loudspeaker module or the second loudspeaker module outputs the first volume value.

8. The sound output device with an earphone mode and a speaker mode as claimed in claim 6, wherein when the USB coder/decoder is electrically coupled to a ground terminal of the first loudspeaker module or the second loudspeaker module, the first loudspeaker module or the second loudspeaker module outputs the second volume value.

9. The sound output device with an earphone mode and a speaker mode as claimed in claim 1, wherein the sound source signal input interface is an audio jack.

10. A sound output device with an earphone mode and a speaker mode, comprising:
a volume output control module, having a Universal Serial Bus (USB) transmission interface and a USB coder/decoder, wherein the USB transmission interface is used for receiving a sound source signal, and the USB coder/decoder is used for amplifying the sound source signal and selectively outputting the amplified sound source signal;
more than one group of first loudspeaker modules, electrically coupled to the volume output control module, for outputting the amplified sound source signal; and
more than one group of second loudspeaker modules, electrically coupled to the volume output control module, for outputting the amplified sound source signal;
wherein when the volume output control module is not electrically coupled to a ground terminal of any one or more of the first loudspeaker modules or the second louder speaker modules, the volume output control module is enabled to output the amplified sound source signal to any one or more of the first loudspeaker modules or the second louder speaker modules;
wherein when the volume output control module is electrically coupled to a ground terminal of any one or more of the first loudspeaker modules or the second louder speaker modules, the volume output control module is disabled to not output the amplified sound source signal to any one or more of the first loudspeaker modules or the second louder speaker modules.
